(19) United States
(12) Patent Application Publication
(10) Pub. No.: US 2011/0122908 A1
(43) Pub. Date: May 26, 2011

(54) SURFACE EMITTING DEVICE

(75) Inventor: Atsushi TATE, Kanagawa-ken (JP)

(73) Assignee: MURATA MANUFACTURING CO., LTD., Kyoto-fu (JP)

(21) Appl. No.: 12/950,539

(22) Filed: Nov. 19, 2010

(30) Foreign Application Priority Data
Nov. 24, 2009 (JP) 2009-265989
Sep. 8, 2010 (JP) 2010-200930

(51) Int. Cl. H01S 5/18; H01L 33/10

(52) U.S. Cl. 372/45.01; 257/98; 257/E33.069

(57) ABSTRACT

Each of a lower reflective layer and an upper reflective layer are formed at a corresponding one of the ends of an optical cavity in the thickness direction. A main active layer is formed in the optical cavity between the lower and upper reflective layers. The optical cavity includes an auxiliary active layer in the vicinity of at least one of the lower reflective layer and a second auxiliary active layer in the vicinity of the upper reflective layer. The auxiliary active layer is located at antinodes of a standing wave where the amplitude of light is large, without increasing the physical length L or optical length Lo between the lower reflective layer and the upper reflective layer.

### CROSS REFERENCE TO RELATED APPLICATIONS

The present application claims priority to Japanese Patent Application No. 2009-265989 filed Nov. 24, 2009, and to Japanese Patent Application No. 2010-200939 filed Sep. 8, 2010, the entire contents of which are incorporated herein by reference in their entirety.

### FIELD OF THE INVENTION

The present invention relates to surface emitting devices such as light-emitting diodes (LEDs) and vertical-cavity surface-emitting lasers (VCSELs).

### BACKGROUND

In general, a surface emitting device has a laminated structure in which a lower reflective layer of a first conductivity type, a plurality of barrier layers, a plurality of active layers each having a single-quantum-well structure or a multiple-quantum-well structure formed between the barrier layers, and an upper reflective layer of a second conductivity type are stacked, in that order, on the upper surface of a substrate of the first conductivity type. A current confinement layer configured to efficiently inject a current into the active layers is formed on one of the lower reflective layer and the upper reflective layer. Thereby, the structure including the lower reflective layer, the plural barrier layers, the active layers, and the upper reflective layer functions as an optical cavity. The lower reflective layer and the upper reflective layer included in the optical cavity are arranged in such a manner that the optical length therebetween is approximately “one-half wavelength of light (λ/2)×(1+n) (where n represents a natural number).”

A first electrode is formed on the lower surface of the substrate. A second electrode is formed on the upper surface of the upper reflective layer. A voltage is applied between the first electrode and the second electrode. The application of a voltage injects a current into the active layers, emitting light from the active layers by stimulated emission. The resulting light is repeatedly reflected between the lower reflective layer and the upper reflective layer, forming the standing wave of light (standing light wave). Each of the active layers is located in the middle portion of the optical cavity and at a corresponding one of antinodes where the maximum amplitude of light is obtained. This increases the electric field of the standing wave propagating through the active layers to enhance the optical output power from each of the active layers, thereby improving the total optical output power. To further improve the optical output power, the number of antinodes of the standing wave is increased by increasing the length of the optical cavity, and an additional active layer is formed at newly formed antinodes of the standing wave (see, for example, Japanese Unexamined Patent Application Publication Nos. 10-27945 and 2007-87994).

However, in the case where the additional active layer is formed at the newly formed antinode of the standing wave obtained by increasing the length of the optical cavity, the increased optical length of the optical cavity disadvantageously leads to weak optical confinement, failing to achieve a sufficient mode gain.

This problem will be described in detail below. The strength of optical confinement for an optical cavity is expressed as an optical confinement factor. The optical confinement factor is defined as the proportion of light confined in the active layer. The ratio (d/L) of the total physical (effective) length d of the active layers to the physical (effective) length L between a pair of reflective layers of the optical cavity is used as an indicator. The mode gain is expressed as the product of a gain coefficient obtained in the active layer and the optical confinement factor and indicates the effective optical gain of the optical cavity. Thus, a weaker optical confinement, i.e., a smaller optical confinement factor, results in a smaller mode gain of a surface emitting device.

### SUMMARY

The invention is directed to a surface emitting device that has a large optical confinement factor and an efficiently increased mode gain.

In an embodiment consistent with the claimed invention, a surface emitting device includes an optical cavity including a first active layer, a pair of reflective layers opposite each other, the first active layer being arranged between the pair of reflective layers, a second active layer formed in the vicinity of at least one of the pair of reflective layers, and a cladding layer formed between the pair of reflective layers. The optical cavity forms a standing wave including antinodes where the maximum amplitude of light is obtained, and each of the antinodes is located in the vicinity of a corresponding one of the pair of reflective layers. The cladding layer is formed by a reduction method for reducing the physical length or optical length of the cladding layer to offset an increase in the physical length or optical length between the pair of reflective layers due to the formation of the cladding layer and the second active layer between the pair of reflective layers.

Forming the second active layer in the vicinity of at least one of the pair of reflective layers permits forming the standing wave including antinodes where the maximum amplitude of light is obtained. Each of the antinodes is located in the vicinity of a corresponding one of the pair of reflective layers. Thus, the amplitude of light can be increased also at the second active layer, which makes it possible to improve the optical output power.

Furthermore, the second active layer is formed in the optical cavity without increasing the optical length between the pair of reflective layers. It is thus possible to suppress an increase in physical length L between the pair of reflective layers as compared with the case where the number of antinodes of the standing wave is increased by increasing the optical length between the pair of reflective layers and where the additional active layer is formed at the newly formed antinode. This can efficiently increase the ratio (d/L), which serves as an indicator of the optical confinement factor, and efficiently increase in mode gain.

Moreover, the cladding layer is formed between the pair of reflective layers by the reduction method for reducing the physical length or optical length thereof. The reduction method enables offsetting an increase in the physical length or optical length between the pair of reflective layers due to the formation of the second active layer. It is thus possible to keep the optical length constant while suppressing an increase in the physical length between the pair of reflective layers included in the optical cavity. This can result in an efficient increase in the ratio (d/L), which serves as an indicator of the optical confinement factor, and an efficient increase in mode gain.

According to a more specific exemplary embodiment, the reduction method includes forming the cladding layer in such a manner that it has a length that offsets an increase in the physical length or optical length between the pair of reflective layers.

In this case, the cladding layer may be formed to have a short physical length to compensate for the second active layer. This can enable offsetting an increase in the physical length or optical length between the pair of reflective layers due to the formation of the second active layer. Thus the optical length between the pair of reflective layers included in the optical cavity can be kept constant.

According to another more specific exemplary embodiment, the reduction method may include forming a film that serves as the cladding layer of a low-refractive-index material such that the cladding layer has a short optical length that offsets said increase in the physical length or optical length between the pair of reflective layers.

In this case, the optical length of the cladding layer may be reduced in response to the second active layer, which enables offsetting an increase in the physical length or optical length between the pair of reflective layers due to the formation of the second active layer. Thus the optical length between the pair of reflective layers included in the optical cavity can be kept constant.

According to yet another more specific exemplary embodiment, the peak wavelength of the gain spectrum of the second active layer may be set to a wavelength longer than the peak wavelength of the gain spectrum of the first active layer, whereby a gain coefficient of the gain spectrum of the second active layer shifted to shorter wavelengths due to a change in operating temperature from room temperature to a low temperature is superimposed on a frequency range where a gain coefficient of the gain spectrum of the first active layer is reduced by the shift of the gain spectrum of the first active layer to shorter wavelengths due to a change in operating temperature from room temperature to a low temperature, complementing a reduction in the gain coefficient of the first active layer.

In this case, the peak wavelength of the gain spectrum of the second active layer may be set to a wavelength longer than the peak wavelength of the gain spectrum of the first active layer. Thus, the gain spectrum of the second active layer shifted to shorter wavelengths due to a change in operating temperature from room temperature to a low temperature may be superimposed on the gain spectrum of the first active layer in a frequency range where the gain coefficient may be reduced by the shift of the gain spectrum of the first active layer to shorter wavelengths due to a change in operating temperature from room temperature to a low temperature, thereby complementing a reduction in the gain coefficient of the first active layer due to a change in operating temperature from room temperature to a low temperature. This can lead to stable operating characteristics even if the operating temperature is changed from room temperature to a low temperature.

According to another more specific exemplary embodiment, the peak wavelength of the gain spectrum of the second active layer may be set to a wavelength shorter than the peak wavelength of the gain spectrum of the first active layer, whereby a gain coefficient of the gain spectrum of the second active layer shifted to longer wavelengths due to a change in operating temperature from room temperature to a high temperature may be superimposed on a frequency range where a gain coefficient of the gain spectrum of the first active layer is reduced by the shift of the gain spectrum of the first active layer to longer wavelengths due to a change in operating temperature from room temperature to a high temperature, complementing a reduction in the gain coefficient of the first active layer.

In this case, the peak wavelength of the gain spectrum of the second active layer may be set to a wavelength shorter than the peak wavelength of the gain spectrum of the first active layer. Thus, the gain spectrum of the second active layer shifted to longer wavelengths due to a change in operating temperature from room temperature to a high temperature may be superimposed on the gain spectrum of the first active layer in a frequency range where the gain coefficient is reduced by the shift of the gain spectrum of the first active layer to longer wavelengths due to a change in operating temperature from room temperature to a high temperature, thereby complementing a reduction in the gain coefficient of the first active layer due to a change in operating temperature from room temperature to a high temperature. This can lead to stable operating characteristics even if the operating temperature is changed from room temperature to a high temperature.

In another embodiment consistent with the claimed invention, a surface emitting device includes an optical cavity including a first active layer, a pair of reflective layers opposite each other, and a second active layer formed in the vicinity of at least one of the pair of reflective layers. The first active layer is arranged between the pair of reflective layers, and the optical cavity forms a standing wave including antinodes where the maximum amplitude of light is obtained. Each of the antinodes is located in the vicinity of a corresponding one of the pair of reflective layers.

In this case, the second active layer makes it possible to improve the optical output power by increasing the amplitude of light at the second active layer in the same way as described above. Furthermore, it is possible to suppress an increase in physical length L between the pair of reflective layers. This can efficiently increase in the ratio (d/L), which serves as an indicator of the optical confinement factor, and efficiently increase mode gain.

Other features, elements, characteristics and advantages of the present invention will become more apparent from the following detailed description of preferred embodiments of the present invention with reference to the attached drawings.

### BRIEF DESCRIPTION OF THE DRAWINGS

FIG. 1 is a cross-sectional view of a vertical-cavity surface-emitting laser device according to a first exemplary embodiment.

FIG. 2 is a cross-sectional view of a vertical-cavity surface-emitting laser device according to a first comparative embodiment.

FIG. 3 is a cross-sectional view of a vertical-cavity surface-emitting laser device according to a second comparative embodiment.

FIG. 4 is a cross-sectional view of a vertical-cavity surface-emitting laser device according to a second exemplary embodiment.

FIG. 5 depicts characteristic curves indicating the gain spectra of a common vertical-cavity surface-emitting laser device at room temperature, a low temperature, and a high temperature.

FIG. 6 depicts characteristic curves indicating the gain spectrum of the vertical-cavity surface-emitting laser device illustrated in FIG. 4 and the gain spectrum of a main active layer alone at room temperature.

FIG. 7 depicts characteristic curves indicating the gain spectrum of the vertical-cavity surface-emitting laser device illustrated in FIG. 4 and the gain spectrum of the main active layer alone at a low temperature.

FIG. 8 is a cross-sectional view of a vertical-cavity surface-emitting laser device according to a third exemplary embodiment.

FIG. 9 depicts characteristic curves indicating the gain spectrum of the vertical-cavity surface-emitting laser device illustrated in FIG. 8 and the gain spectrum of a main active layer alone at room temperature.

FIG. 10 depicts characteristic curves indicating the gain spectrum of the vertical-cavity surface-emitting laser device illustrated in FIG. 8 and the gain spectrum of the main active layer alone at a high temperature.

### DETAILED DESCRIPTION

Exemplary embodiments of the present invention will be described in detail below using exemplary vertical-cavity surface-emitting laser devices (hereinafter, referred to as “VCSELs”) with reference to the attached drawings.

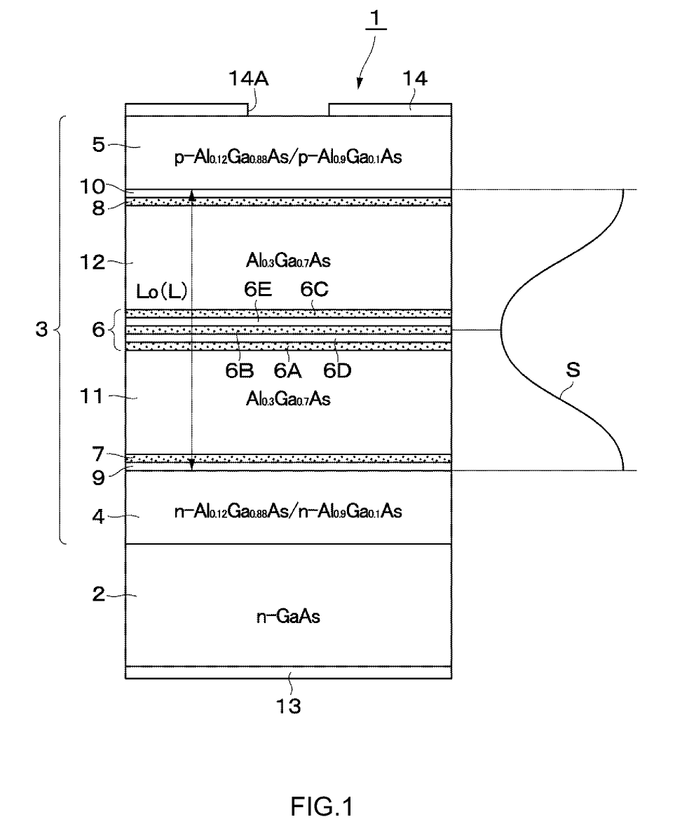

FIG. 1 shows a VCSEL 1 according to a first exemplary embodiment. VCSEL 1 has a laminated structure in which a lower reflective layer 4, a first barrier layer 9, a first auxiliary active layer 7 (second active layer), a first cladding layer 11, a main active layer 6 (first active layer), a second cladding layer 12, a second auxiliary active layer 8 (second active layer), a second barrier layer 10, and an upper reflective layer 5 are sequentially stacked on the upper surface of a substrate 2. An optical cavity 3 is formed of the lower reflective layer 4, the first barrier layer 9, the first auxiliary active layer 7, the first cladding layer 11, the main active layer 6, the second cladding layer 12, the second auxiliary active layer 8, the second barrier layer 10, and the upper reflective layer 5. Although not shown, the upper reflective layer 5 is provided with a current confinement layer. Furthermore, a contact layer (not shown) is provided on the uppermost portion of the upper reflective layer 5 in order to form an ohmic contact with a p-type electrode 14 described below.

An n-type electrode 13 is formed on the lower surface of the substrate 2, and a p-type electrode 14 is formed on the upper surface of the upper reflective layer 5. The lower reflective layer 4, the first barrier layer 9, the first auxiliary active layer 7, the first cladding layer 11, the main active layer 6, the second cladding layer 12, the second auxiliary active layer 8, the second barrier layer 10, and the upper reflective layer 5 can be formed by an epitaxial growth technique such as metal-organic chemical vapor deposition (MOCVD). The n-type electrode 13 and the p-type electrode 14 are formed of conductive thin metal films and formed by, for example, evaporation or sputtering. An opening 14A configured to emit light is formed in the central portion of the p-type electrode 14.

The substrate 2 is formed of, for example, a substrate having a thickness of about several hundred micrometers and being composed of a compound semiconductor of n-type single-crystal gallium arsenide (n-GaAs).

The lower reflective layer 4 is constituted by an n-type distributed Bragg reflector (DBR) in which a plurality of thin layers composed of an n-type compound semiconductor of n-type single-crystal aluminum gallium arsenide (n-Al_{0.12}Ga_{0.88}As) having an Al content of, for example, about 12% and a plurality of thin layers composed of an n-type compound semiconductor of n-type single-crystal aluminum gallium arsenide (n-Al_{0.9}Ga_{0.1}As) having an Al content of, for example, about 90% are alternately stacked (for example, about 30 layers each). The optical length of each of the thin layers composed of single-crystal n-Al_{0.12}Ga_{0.88}As and the thin layers composed of single-crystal n-Al_{0.9}Ga_{0.1}As is set to about λ/4 with respect to the wavelength λ (e.g., λ=about 850 nm) of light generated in the optical cavity 3. Note that the optical length is calculated by multiplying the physical (effective) length of the thickness by the refractive index of the layer (medium).

Like the lower reflective layer 4, the upper reflective layer 5 is constituted by a p-type distributed Bragg reflector in which a plurality of thin layers composed of a p-type compound semiconductor of p-type single-crystal aluminum gallium arsenide (p-Al_{0.12}Ga_{0.88}As) having an Al content of, for example, about 12% and a plurality of thin layers composed of a p-type compound semiconductor of p-type single-crystal aluminum gallium arsenide (p-Al_{0.9}Ga_{0.1}As) having an Al content of, for example, about 90% are alternately stacked (for example, about 10 layers each). The optical length of each of the thin layers composed of single-crystal p-Al_{0.12}Ga_{0.88}As and the thin layers composed of single-crystal p-Al_{0.9}Ga_{0.1}As is set to about λ/4 with respect to the wavelength λ (e.g., λ=about 850 nm) of light generated in the optical cavity 3.

The lower reflective layer 4 and the upper reflective layer 5 included in the optical cavity 3 are spaced in such a manner that the optical length Lo between the lower reflective layer 4 and the upper reflective layer 5 is comparable to, for example, the wavelength λ (about 850 nm) of light.

The main active layer 6 is arranged in the middle portion of the optical cavity 3 in the thickness direction. The main active layer 6 has a multiple-quantum-well structure that includes, for example, three well sublayers 6A, 6B, and 6C functioning as quantum wells. Each of the well sublayers 6A, 6B, and 6C is composed of, for example, single-crystal gallium arsenide (GaAs) and has a thickness of about several nanometers. A barrier layer 6D is formed between the well layers 6A and 6B. A barrier layer 6E is formed between the well sublayers 6B and 6C. Each of the barrier layers 6D and 6E is composed of, for example, single-crystal aluminum gallium arsenide (Al_{0.3}Ga_{0.7}As) having an aluminum content of about 30% and has a thickness of about several nanometers.

The first auxiliary active layer 7 is arranged in the vicinity of the lower reflective layer 4 with the first barrier layer 9. The first auxiliary active layer 7 has a single-quantum-well structure. Like the well sublayers 6A, 6B, and 6C of the main active layer 6, the first auxiliary active layer 7 is composed of, for example, single-crystal gallium arsenide (GaAs) and has a thickness of about several nanometers. The first barrier layer 9 is composed of, for example, single-crystal aluminum gallium arsenide (Al_{0.3}Ga_{0.7}As) having an aluminum content of about 30%.

The second auxiliary active layer 8 is arranged in the vicinity of the upper reflective layer 5 with the second barrier layer 10. The second auxiliary active layer 8 has a single-quantum-well structure. Like the first auxiliary active layer 7, the second auxiliary active layer 8 is composed of, for example, single-crystal gallium arsenide (GaAs) and has a thickness of about several nanometers. The second barrier layer 10 is composed of, for example, single-crystal aluminum gallium arsenide (Al_{0.3}Ga_{0.7}As) having an aluminum content of about 30%. The peak wavelength of the gain spectrum of each of the first auxiliary active layer 7 and the second auxiliary active layer 8 is set to substantially the same value as that of the main active layer 6.

As described below, antinodes where the maximum amplitude of light in a standing wave S is obtained are located at the first auxiliary active layer 7, the main active layer 6, and the second auxiliary active layer 8. Note that the maximum intensity of light is obtained at the antinodes where the maximum amplitude of light is obtained. Thus, the arrangement of the first auxiliary active layer 7 to a position as close to the lower reflective layer 4 as possible improves the optical output power from the first auxiliary active layer 7. Similarly, the arrangement of the second auxiliary active layer 8 to a position as close to the upper reflective layer 5 as possible improves the optical output power from the second auxiliary active layer 8.

However, an excessively short physical (effective) length of each of the first barrier layer 9 and the second barrier layer 10 possibly results in excessively short distances between the first auxiliary active layer 7 and the lower reflective layer 4 and between the second auxiliary active layer 8 and the upper reflective layer 5, reducing the film quality of the first auxiliary active layer 7 and the second auxiliary active layer 8. Thus, the thickness of the first barrier layer 9 is preferably set to a minimum possible value to the extent that a sufficient distance between the first auxiliary active layer 7 and the lower reflective layer 4 is obtained. Usually, the thickness of the first barrier layer 9 is set to a minimum possible value such as about 5 nm.

Like the first barrier layer 9, the thickness of the second barrier layer 10 is preferably set to a minimum possible value to the extent that a sufficient distance between the second auxiliary active layer 8 and the upper reflective layer 5 is obtained. Usually, the thickness of the second barrier layer 10 is set to a minimum possible value such as about 5 nm.

The first cladding layer 11 is arranged between the first auxiliary active layer 7 and the main active layer 6. The second cladding layer 12 is arranged between the main active layer 6 and the second auxiliary active layer 8. Each of the first cladding layer 11 and the second cladding layer 12 is composed of, for example, single-crystal aluminum gallium arsenide (Al_{0.3}Ga_{0.7}As) having an aluminum content of about 30%.

The total optical length of the first cladding layer 11 and the second cladding layer 12 is determined by subtracting the optical lengths of the main active layer 6, the first auxiliary active layer 7, the second auxiliary active layer 8, the first barrier layer 9, and the second barrier layer 10 from the optical length Lo between the lower reflective layer 4 and the upper reflective layer 5.

Specifically, the optical length Lo between the lower reflective layer 4 and the upper reflective layer 5 is set to, for example, a value comparable to the wavelength λ of light (about 850 nm). The optical length of the main active layer 6 is set to about 160 nm. The optical length of each of the first auxiliary active layer 7 and the second auxiliary active layer 8 is set to about 30.8 nm. The optical length of each of the first barrier layer 9 and the second barrier layer 10 is set to about 33.8 nm. In this case, the total optical length of the first cladding layer 11 and the second cladding layer 12 is set to about 560.4 nm.

The first cladding layer 11 and the second cladding layer 12 are usually formed so as to have the same optical length, so that each of the first cladding layer 11 and the second cladding layer 12 has an optical length of about 280.4 nm. Thus, the physical (effective) lengths of the first cladding layer 11 and the second cladding layer 12 in the thickness direction are also reduced by values corresponding to, for example, the respective first auxiliary active layer 7 and the second auxiliary active layer 8. In this way, the optical lengths of the first cladding layer 11 and the second cladding layer 12 are adjusted by a reduction method to offset the optical lengths of the first auxiliary active layer 7 and the second auxiliary active layer 8, so that the optical length Lo between the lower reflective layer 4 and the upper reflective layer 5 included in the optical cavity 3 is kept constant.

Furthermore, the first cladding layer 11 and the second cladding layer 12 increase the electron and hole densities of the main active layer 6, the first auxiliary active layer 7, and the second auxiliary active layer 8 and function to confine light to the main active layer 6, the first auxiliary active layer 7, and the second auxiliary active layer 8 in the same way as in the first barrier layer 9 and the second barrier layer 10.

The VCSEL 1 according to this embodiment has the foregoing structure. The operation of the VCSEL 1 will be described below.

The application of a voltage between the n-type electrode 13 and the p-type electrode 14 injects a current into the first auxiliary active layer 7, the main active layer 6, and the second auxiliary active layer 8, thus exciting the well sublayers 6A to 6C and so forth included in these layers and causing stimulated emission of light. The resulting light is repeatedly reflected between the lower reflective layer 4 and the upper reflective layer 5, forming the standing wave S between the lower reflective layer 4 and the upper reflective layer 5 and emitting light having a wavelength of λ through the opening 14A. The standing wave S with a length corresponding to one wavelength λ of light is formed in the optical cavity 3. An antinode where the maximum amplitude of the standing wave S is obtained is located at each of the main active layer 6, first auxiliary active layer 7, and the second auxiliary active layer 8.

In the standing wave S, the maximum light intensity is obtained at the antinodes where the maximum amplitude of light is obtained. That is, the maximum intensity of the standing wave S is obtained at the main active layer 6, the first auxiliary active layer 7, and the second auxiliary active layer 8. Thus, the first auxiliary active layer 7 and the second auxiliary active layer 8 make it possible to improve the optical output power.

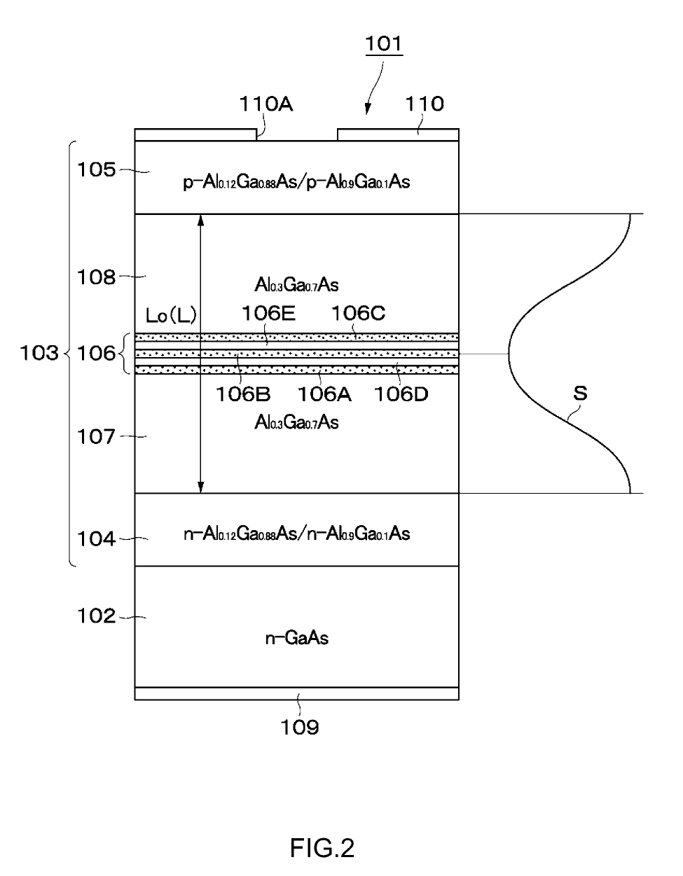

The optical confinement factor of the VCSEL 1 according to the first exemplary embodiment will be described below in comparison with the optical confinement factor of a VCSEL 101 shown in FIG. 2, which does not include the first auxiliary active layer 7 and the second auxiliary active layer 8, according to a first comparative embodiment. Note that the optical length of the optical cavity of the VCSEL 101 is equal to that of the VCSEL 1.

As shown in FIG. 2, VCSEL 101 according to the first comparative embodiment includes an optical cavity 103 on the upper surface of a substrate 102. The optical cavity 103 includes a lower reflective layer 104, a first cladding layer 107, an active layer 106, a second cladding layer 108, and an upper reflective layer 105 stacked in that order. An n-type electrode 109 is formed on the substrate 102. A p-type electrode 110 having an opening 110A is formed on the upper surface of the upper reflective layer 105.

As with the VCSEL 1 according to the first exemplary embodiment, also in the case of the VCSEL 101, the optical length Lo of the optical cavity 103 is set to a value comparable to the wavelength λ of light. For the VCSEL 101 according to the first comparative embodiment, the active layer 106 including, for example, three well sublayers 106A, 106B, and 106C is formed at an antinode of the standing wave S. A barrier layer 106D is formed between the well sublayers 106A and 106B. A barrier layer 106E is formed between the well sublayers 106B and 106C.

For the first comparative embodiment, however, the total physical length d of the active layer 106 is reduced by the thicknesses of the first and second auxiliary active layers 7 and 8, as compared with that in the first embodiment. Thus, the ratio (d/L) serving as an indicator of an optical confinement factor is reduced compared with that in the first embodiment. Specifically, the ratio (d/L) in the VCSEL 1 is about 0.059, whereas the ratio (d/L) in the VCSEL 101 is about 0.034.

The optical confinement factor of the VCSEL 1 according to the first exemplary embodiment will be described below in comparison with the optical confinement factor of a VCSEL 121 according to a second comparative embodiment in which the number of antinodes of the standing wave is increased by increasing the optical length of the optical cavity and in which an active layer is further formed at the newly formed antinode.

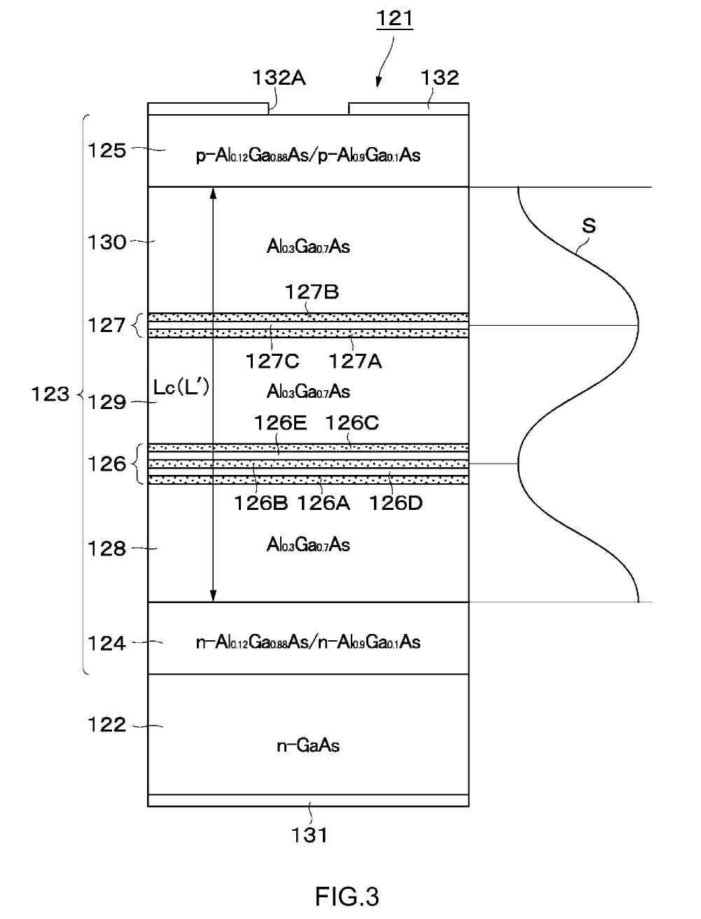

FIG. 3 illustrates the VCSEL 121 according to the second comparative embodiment. The VCSEL 121 includes an optical cavity 123 on the upper surface of a substrate 122. The optical cavity 123 includes a lower reflective layer 124, a first cladding layer 128, an active layer 126, a second cladding layer 129, an active layer 127, a third cladding layer 130, and an upper reflective layer 125 stacked in that order. An n-type electrode 131 is formed on the lower surface of the substrate 122. A p-type electrode 132 having an opening 132A is formed on the upper surface of the upper reflective layer 125.

The optical length of the optical cavity 3 of the VCSEL 1 according to the first embodiment is set to a value equal to the wavelength λ of light, whereas the optical length Lc of the optical cavity 123 of the VCSEL 121 according to the second comparative embodiment is set to, for example, a value about 1.5 times the wavelength λ of light. In this case, a standing wave S having a length about 1.5 times the wavelength λ of light is formed in the optical cavity 123 of the VCSEL 121. A new antinode where the maximum amplitude is obtained is formed in the middle portion of the standing wave S.

Thus, in the VCSEL 121 according to the second comparative embodiment, two antinodes are located in the middle portion of the standing wave S. The active layer 126 including, for example, three well sublayers 126A, 126B, and 126C is formed at a portion where one of the two antinodes is located close to the lower reflective layer 124. A barrier layer 126D is formed between the well sublayers 126A and 126B. A barrier layer 126E is formed between the well sublayers 126B and 126C.

In addition, the active layer 127 including two well sublayers 127A and 127B is formed at a position corresponding to the new antinode, i.e., at a portion where one of the two antinodes, which are located in the middle portion of the standing wave S, is located close to the upper reflective layer 125. A barrier layer 127C is formed between the well sublayers 127A and 127B. The cladding layer 129 is formed between the active layers 126 and 127. Thus, the total physical (effective) length of the active layers included in the optical cavity 123 between the lower reflective layer 124 and the upper reflective layer 125 is increased by the thicknesses of the well sublayers 127A and 127B compared with the case where only the active layer 126 is formed.

However, the physical (effective) length L′ between the lower reflective layer 124 and the upper reflective layer 125 of the optical cavity 123 according to the second comparative embodiment is as large as about 1.5 times the physical (effective) length L between the lower reflective layer 4 and the upper reflective layer 5 of the optical cavity 3 according to the first exemplary embodiment. Thus, the ratio (d/L′) serving as an indicator of an optical confinement factor is not increased. Therefore, formation of the active layer 127 is ineffective. Specifically, the ratio (d/L) in the VCSEL 1 is about 0.059, whereas the ratio (d/L′) in the VCSEL 121 is about 0.054.

Thus, the mode gain is efficiently increased in the VCSEL 1 according to the first exemplary embodiment compared with the VCSELs 101 and 121 according to the first and second comparative embodiments.

As described above, according to the first exemplary embodiment, each of the auxiliary active layers 7 and 8 is formed in the vicinity of a corresponding one of the lower reflective layer 4 and the upper reflective layer 5, which are located at the antinodes of the standing wave S, thereby increasing the amplitude of light also at the auxiliary active layers 7 and 8. That is, the auxiliary active layers 7 and 8 make it possible to improve the optical output power.

Furthermore, the auxiliary active layers 7 and 8 are formed in the optical cavity 3 without increasing the optical length Lo between the lower reflective layer 4 and the upper reflective layer 5. It is thus possible to suppress an increase in physical length L between the lower reflective layer 4 and the upper reflective layer 5 as compared with the VCSEL 121 according to the second comparative embodiment in which the number of antinodes of the standing wave S is increased by increasing the optical length Lc between the lower reflective layer 124 and the upper reflective layer 125 and in which the additional active layer 127 is formed at the newly formed antinode. This can therefore result in an efficient increase in ratio (d/L), which serves as an indicator of the optical confinement factor, and an efficient increase in mode gain.

In addition, the active layer 127 including two well sublayers 127A and 127B is formed at a position corresponding to the new antinode, i.e., at a portion where one of the two antinodes, which are located in the middle portion of the standing wave S, is located close to the upper reflective layer 125. A barrier layer 127C is formed between the well sublayers 127A and 127B. The cladding layer 129 is formed between the active layers 126 and 127. Thus, the total physical (effective) length of the active layers included in the optical cavity 123 between the lower reflective layer 124 and the upper reflective layer 125 is increased by the thicknesses of the well sublayers 127A and 127B compared with the case where only the active layer 126 is formed.

However, the physical (effective) length L′ between the lower reflective layer 124 and the upper reflective layer 125 of the optical cavity 123 according to the second comparative embodiment is as large as about 1.5 times the physical (effective) length L between the lower reflective layer 4 and the upper reflective layer 5 of the optical cavity 3 according to the first embodiment. Thus, the ratio (d/L′) serving as an indicator of an optical confinement factor is not increased. Hence, the formation of the active layer 127 is ineffective. Specifically, the ratio (d/L) in the VCSEL 1 is about 0.059, whereas the ratio (d/L′) in the VCSEL 121 is about 0.054. Thus, the mode gain is efficiently increased in the VCSEL 1 according to the first exemplary embodiment compared with the VCSEL 101, 121 according to the first or second comparative embodiments.

As described above, according to the first exemplary embodiment, each of the auxiliary active layers 7 and 8 is formed in the vicinity of a corresponding one of the lower reflective layer 4 and the upper reflective layer 5, which are located at the antinodes of the standing wave S, thereby increasing the amplitude of light also at the auxiliary active layers 7 and 8. That is, the auxiliary active layers 7 and 8 make it possible to improve the optical output power.

Furthermore, the auxiliary active layers 7 and 8 are formed in the optical cavity 3 without increasing the optical length Lo between the lower reflective layer 4 and the upper reflective layer 5. It is thus possible to suppress an increase in physical length L between the lower reflective layer 4 and the upper reflective layer 5 as compared with the VCSEL 121 according to the second comparative embodiment in which the number of antinodes of the standing wave S is increased by increasing the optical length Lc between the lower reflective layer 124 and the upper reflective layer 125 and in which the additional active layer 127 is formed at the newly formed antinode. This can therefore result in an efficient increase in ratio (d/L), which serves as an indicator of the optical confinement factor, and an efficient increase in mode gain.

In addition, the cladding layers 11 and 12 are formed between the lower reflective layer 4 and the upper reflective layer 5 by a reduction method for reducing the physical lengths of the cladding layers 11 and 12. The reduction method enables offsetting an increase in the physical length L or optical length Lo between the lower reflective layer 4 and the upper reflective layer 5 due to the formation of the auxiliary active layers 7 and 8. It is thus possible to keep the optical length Lo constant while suppressing an increase in the physical length L between the lower reflective layer 4 and the upper reflective layer 5 included in the optical cavity 3. This therefore results in an efficient increase in ratio (d/L), which serves as an indicator of the optical confinement factor, and an efficient increase in mode gain.

In the first exemplary embodiment, the reduction method includes forming the first cladding layer 11 and the second cladding layer 12 in such a manner that each of the first cladding layer 11 and the second cladding layer 12 has a short physical (effective) length. However, the present invention is not limited to this reduction method. As another reduction method, for example, the first cladding layer 11 and the second cladding layer 12 can be formed, without changing their physical (effective) lengths, using a material having a lower refractive index than that of the cladding layer used when the first auxiliary active layer 7 and the second auxiliary active layer 8 are not formed. In this case, since the optical length of each of the first cladding layer 11 and the second cladding layer 12 is given by the product of the physical (effective) length of the thickness and the refractive index of the layer (medium), each of the first cladding layer 11 and the second cladding layer 12 has a short optical length. Hence, another reduction method provides the same effect as in the case where the physical (effective) length is changed.

Instead of changing the physical (effective) lengths of the first cladding layer 11 and the second cladding layer 12, the physical (effective) lengths of the first barrier layer 9 and the second barrier layer 10 can be changed. However, excessively short physical (effective) lengths of the first barrier layer 9 and the second barrier layer 10 are likely to cause a reduction in the quality of the first auxiliary active layer 7 and the second auxiliary active layer 8. It is thus desirable to change the physical (effective) lengths of the first cladding layer 11 and the second cladding layer 12.

Moreover, in the first exemplary embodiment, the first auxiliary active layer 7 and the second auxiliary active layer 8 are formed at respective positions below and above the main active layer 6. Alternatively, only one of the first auxiliary active layer 7 and the second auxiliary active layer 8 can be formed.

In addition, in the first embodiment, each of the first auxiliary active layer 7 and the second auxiliary active layer 8 has a single quantum well structure. Alternatively, each of them can have a multiple-quantum-well structure.

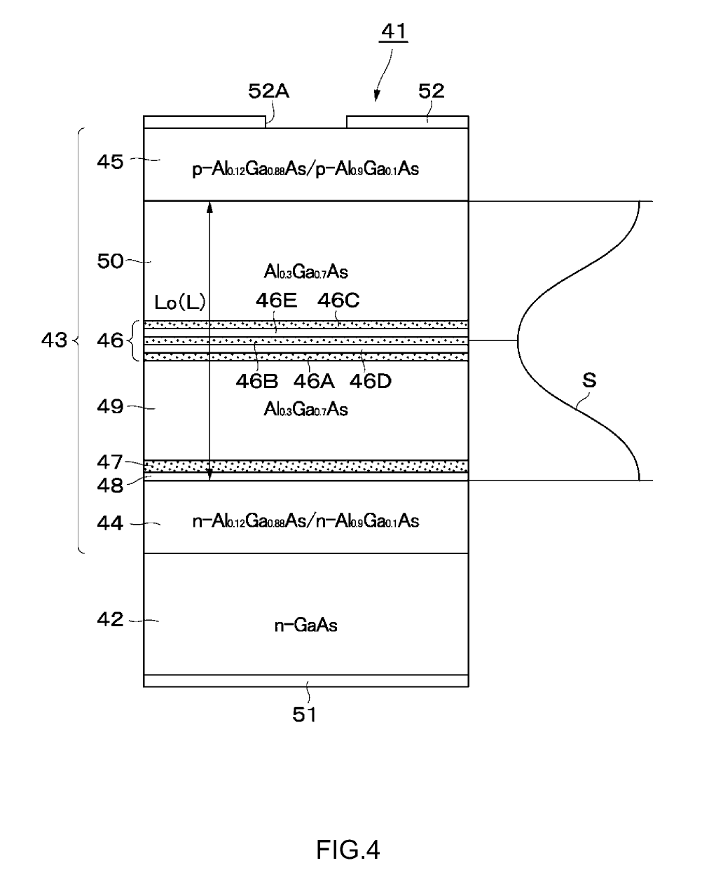

A second exemplary embodiment will be described below with reference to FIG. 4. A first feature of the second exemplary embodiment is the formation of an auxiliary active layer located close to one of an upper reflective layer and a lower reflective layer or is the formation of auxiliary active layers located close to both of an upper reflective layer and a lower reflective layer included in an optical cavity of a VCSEL. A second feature is the fact that the peak wavelength of the gain spectrum of the auxiliary active layer is set to a wavelength longer than the peak wavelength of the gain spectrum of a main active layer in order to improve operation at low temperatures. In the second exemplary embodiment illustrated in FIG. 4, descriptions will be made by taking the case where the auxiliary reflective layer is formed close to the lower reflective layer as an example.

A VCSEL 41 according to the second exemplary embodiment includes an optical cavity 43 on the upper surface of a substrate 42. The optical cavity 43 includes a lower reflective layer 44, a barrier layer 48, an auxiliary active layer 47 (second active layer), a first cladding layer 49, a main active layer 46 (first active layer), a second cladding layer 50, and an upper reflective layer 45 stacked in that order. An n-type electrode 51 is formed on the lower surface of the substrate 42. A p-type electrode 52 having an opening 52A is formed on the upper surface of the upper reflective layer 45.

The substrate 42, the lower reflective layer 44, and the upper reflective layer 45 according to the second exemplary embodiment are formed in substantially the same way as the substrate 2, the lower reflective layer 4, and the upper reflective layer 5, respectively, according to the first exemplary embodiment.

The lower reflective layer 44 and the upper reflective layer 45 included in the optical cavity 43 are spaced in such a manner that the optical length Lo between the lower reflective layer 44 and the upper reflective layer 45 is comparable to, for example, the wavelength λ (about 850 nm) of light.

The main active layer 46 is arranged in the middle portion of the optical cavity 43 in the thickness direction. The main active layer 46 has a multiple-quantum-well structure that includes, for example, three well sublayers 46A, 46B, and 46C functioning as quantum wells. Each of the well sublayers 46A, 46B, and 46C is composed of, for example, single-crystal gallium arsenide (GaAs) and has a thickness of about several nanometers. A barrier layer 46D is formed between the well layers 46A and 46B. A barrier layer 46E is formed between the well sublayers 46B and 46C. Each of the barrier layers 46D and 46E is composed of, for example, single-crystal aluminum gallium arsenide (Al_{0.3}Ga_{0.7}As) having an aluminum content of about 30% and has a thickness of about several nanometers. The peak wavelength of the gain spectrum of the main active layer 46 is set to, for example, about 835 nm.

The auxiliary active layer 47 is arranged in the vicinity of the lower reflective layer 44 with the barrier layer 48. The auxiliary active layer 47 has a single-quantum-well structure. Like the well sublayers 46A, 46B, and 46C of the main active layer 46, the auxiliary active layer 47 is composed of, for example, single-crystal gallium arsenide (GaAs) and has a thickness of about several nanometers. The barrier layer 48 is composed of, for example, single-crystal aluminum gallium arsenide (Al_{0.3}Ga_{0.7}As) having an aluminum content of about 30%. The peak wavelength of the gain spectrum of the auxiliary active layer 47 is set to, for example, about 848 nm so as to be longer than the peak wavelength of the gain spectrum of the main active layer 46.

A standing wave S with a length corresponding to one wavelength of light having a wavelength of λ is formed in the optical cavity 43. In this case, the main active layer 46 and the auxiliary active layer 47 are located at antinodes where the maximum amplitude of light in the standing wave S is obtained.

The first cladding layer 49 is arranged between the auxiliary active layer 47 and the main active layer 46. The second cladding layer 50 is arranged between the main active layer 46 and the upper reflective layer 45. Each of the first cladding layer 49 and the second cladding layer 50 is composed of, for example, single-crystal aluminum gallium arsenide (Al_{0.3}Ga_{0.7}As) having an aluminum content of about 30%.

The total optical length of the first cladding layer 49 and the second cladding layer 50 is determined by subtracting the optical lengths of the main active layer 46, the auxiliary active layer 47, and the barrier layer 48 from the optical length Lo between the lower reflective layer 44 and the upper reflective layer 45. The main active layer 46 is arranged in the middle portion of the optical cavity 43 in the thickness direction. Thus, for example, the total optical length of the first cladding layer 49, the auxiliary active layer 47, and the barrier layer 48 is set to a value substantially equal to the optical length of the second cladding layer 50.

Hence, the physical (effective) length of the first cladding layer 49 in the thickness direction is reduced by a value corresponding to, for example, the auxiliary active layer 47 with respect to the physical (effective) length of the second cladding layer 50. In this way, the optical length of the first cladding layer 49 is adjusted by a reduction method to offset the optical length of the auxiliary active layer 47, so that the optical length Lo between the lower reflective layer 44 and the upper reflective layer 45 included in the optical cavity 43 is kept constant.

The VCSEL 41 according to the second exemplary embodiment has the foregoing structure. The light-emitting operation of the VCSEL 41 is the same as that of the VCSEL 1 according to the first exemplary embodiment. The VCSEL 41 has the same effect as in the first exemplary embodiment. Furthermore, in the second exemplary embodiment, the auxiliary active layer 47 exhibiting the gain spectrum whose peak wavelength is longer than the peak wavelength of the gain spectrum of the main active layer 46 is formed, thereby leading to stable operating characteristics even if the operating temperature is changed from room temperature to a low temperature. This effect will be specifically described below.

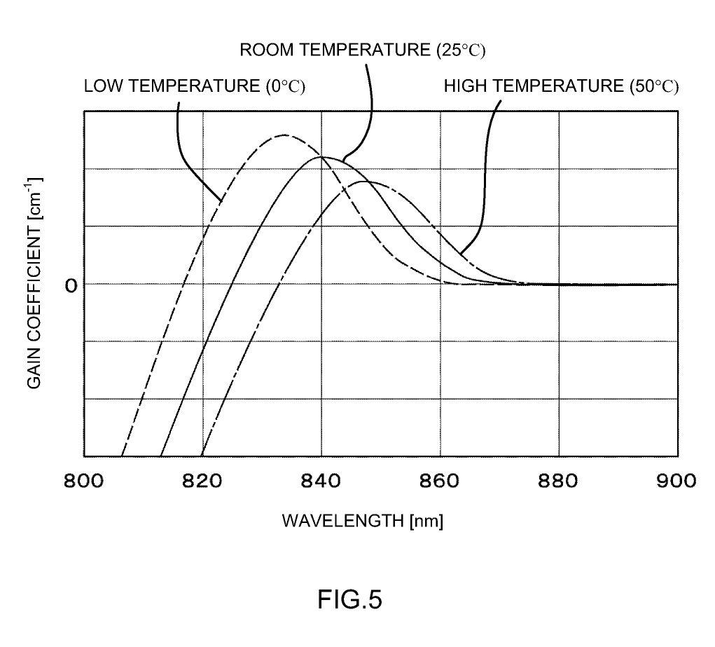

FIG. 5 illustrates a common gain spectrum of light produced from an active layer having a quantum-well structure by stimulated emission. The horizontal axis of the gain spectrum indicates the wavelength (nm). The vertical axis indicates the gain coefficient (cm⁻¹). Note that when the active layer has a multiple-quantum-well structure, the resulting gain spectrum is given by the superimposition of gain spectra of quantum wells included in the active layer. The gain coefficient of the gain spectrum is reduced as the wavelength is changed from the peak wavelength to shorter wavelengths. At a specific wavelength or less, the gain coefficient is changed from a positive value to a negative value because light having the wavelength is absorbed and lost. The gain coefficient is reduced as the wavelength is changed from the peak wavelength to longer wavelengths. In this case, the gain coefficient is not changed into a negative value because light is not absorbed or lost. That is, as the wavelength is changed from the peak wavelength to longer wavelengths, the gain coefficient approaches the horizontal axis (zero).

When the operating temperature of the VCSEL is changed from room temperature to a low temperature, the gain spectrum of the active layer shifts entirely to shorter wavelengths and changes similarly in such a manner that the maximum gain coefficient is increased.

The resonant wavelength λ0 of light emitted from the VCSEL 41 is determined by the optical length Lo between the upper reflective layer 45 and the lower reflective layer 44 included in the optical cavity 43 of the VCSEL 41. The coefficient of linear expansion and the refractive index of each of media constituting the optical cavity 43 are not significantly changed. So, the resonant wavelength λ0 of light is not significantly changed. The temperature characteristics of the VCSEL 41 are thus dominated by the temperature dependence of the quantum wells constituting the main active layer 46 and the auxiliary active layer 47.

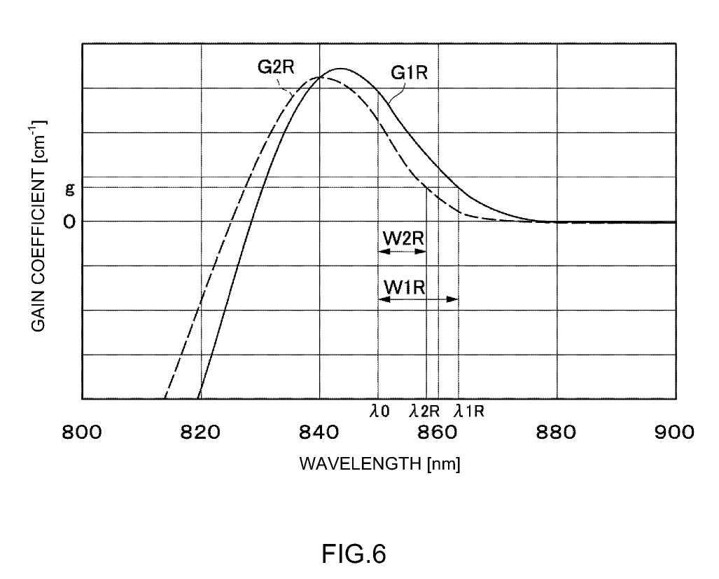

FIG. 6 illustrates the gain spectrum G1R of the VCSEL 41 including the main active layer 46 and the auxiliary active layer 47 in simulations at room temperature. The gain spectrum G1R has a profile obtained by the superimposition of the gain spectrum of the main active layer 46 and the gain spectrum (not shown) of the auxiliary active layer 47. To demonstrate the effect of the auxiliary active layer 47 formed in the VCSEL 41, FIG. 6 also illustrates the gain spectrum G2R of a VCSEL including the main active layer 46 without the auxiliary active layer 47 in simulations. The simulations were performed under conditions described below. The peak wavelength of the gain spectrum of the main active layer 46 was set to about 835 nm. The peak wavelength of the gain spectrum of the auxiliary active layer 47 was set to about 848 nm. The number of carriers injected into the main active layer 46 was identical to the number of carriers injected into the auxiliary active layer 47. For example, the number of carriers was about 2.0×10¹⁸ carriers/cm³. Furthermore, the resonant wavelength λ0 of the VCSEL 41 is set in a frequency range where the gain coefficient of the gain spectrum G1R is positive.

The peak wavelength of the gain spectrum of the auxiliary active layer 47 is selected in such a manner that the gain coefficient of the gain spectrum G1R is larger than the gain coefficient of the gain spectrum G2R in a frequency range corresponding to wavelengths longer than the peak wavelength of the gain spectrum G2R when the gain spectrum of the auxiliary active layer 47 is superimposed on the gain spectrum G2R of the main active layer 46. Wavelengths (frequencies) on the longer-wavelength side when each of the gain coefficient of the gain spectrum G1R and the gain coefficient of the gain spectrum G2R is set to, for example, g (g>0), are set to λ1R and λ2R, respectively. In the case where the frequency range between the resonant wavelength λ0 and the wavelength λ1R is set to W1R and where the frequency range between the resonant wavelength λ0 and the wavelength λ2R is set to W2R, the frequency range W1R is wider than the frequency range W2R.

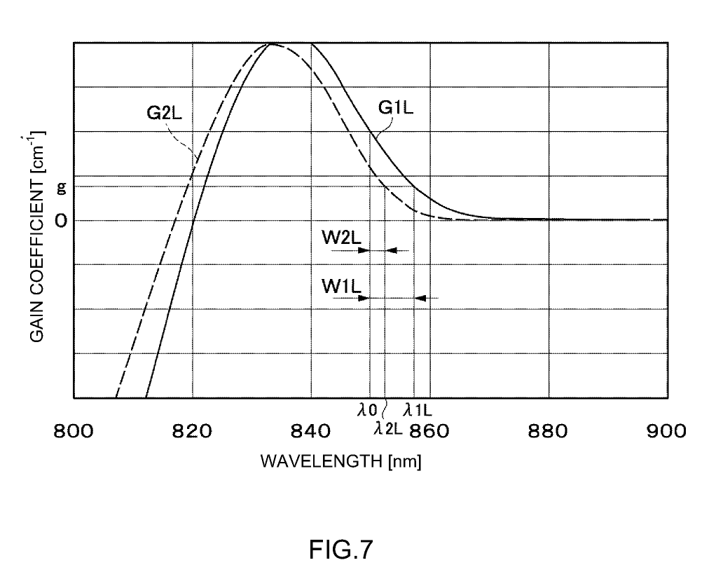

Next, in the case where the operating temperature of the VCSEL 41 is changed from room temperature (e.g., about 25° C.) to a low temperature (e.g., about 0° C.), descriptions will be made with reference to FIG. 7.

When the operating temperature is changed from room temperature to a low temperature, the gain spectrum G1R shown in FIG. 6 is shifted to shorter wavelengths and changed into a gain spectrum G1L. Furthermore, the gain spectrum G2R is also shifted to shorter wavelengths and changed into a gain spectrum G2L.

Wavelengths (frequencies) on the longer-wavelength side when each of the gain coefficient of the gain spectrum G1L and the gain coefficient of the gain spectrum G2L is set to, for example, g, are set to λ1L and λ2L, respectively. The frequency range between the resonant wavelength λ0 and the wavelength λ1L is set to W1L. The frequency range between the resonant wavelength λ0 and the wavelength λ2L is set to W2L.

In this case, since the gain spectrum G2R is shifted to shorter wavelengths, the frequency range W2L is narrower than the frequency range W2R. Meanwhile, the frequency range W1R is wider than the frequency range W2R. Unlike the frequency range W2L, the frequency range W1L is not significantly narrow but is comparable to the frequency range W2R even if the gain spectrum G1R is shifted to shorter wavelengths. It is thus possible to ensure a gain coefficient profile similar to the gain spectrum G2R in a frequency range corresponding to wavelengths longer than the peak wavelength of the gain spectrum G1L even if the operating temperature of the VCSEL 41 is changed from room temperature to a low temperature.

The gain coefficient of the gain spectrum G1L is larger than that of the gain spectrum G1R in a frequency range corresponding to wavelengths shorter than the peak wavelength of the gain spectrum G1L. It is thus possible to ensure a wide frequency range where the gain coefficient is positive in a wavelength range including the resonant wavelength λ0 in comparison with the case where the main active layer 46 is formed without the formation of the auxiliary active layer 47. Hence, the VCSEL 41 operates stably even if the operating temperature is changed from room temperature to a low temperature. That is, the formation of the auxiliary active layer 47 complements a reduction in gain coefficient in a frequency range corresponding to wavelengths longer than the peak wavelength. Furthermore, an increase in gain coefficient in a frequency range corresponding to wavelengths shorter than the peak wavelength allows the VCSEL 41 to operate stably even if the operating temperature is changed from room temperature to a low temperature.

In the foregoing second exemplary embodiment, the auxiliary active layer 47 is formed at one position below the main active layer 46. Like the first exemplary embodiment, auxiliary active layers can be formed at positions above and below the main active layer. Alternatively, an auxiliary active layer can be formed at one position above the main active layer.

In the foregoing second exemplary embodiment, the auxiliary active layer 47 has a single-quantum-well structure. Alternatively, the auxiliary active layer 47 can have a multiple-quantum-well structure.

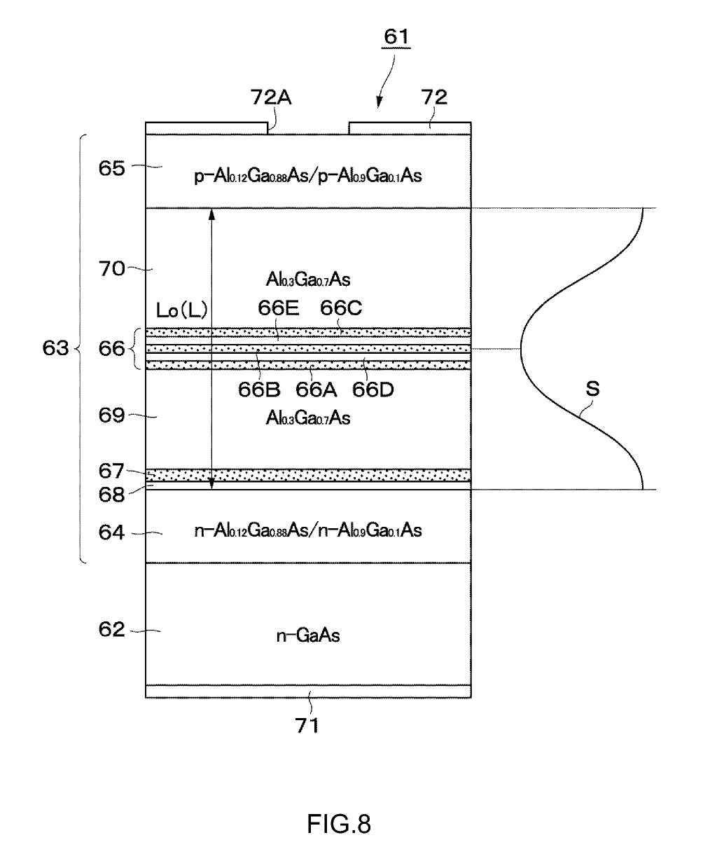

A third exemplary embodiment will be described below with reference to FIG. 8. A first feature of the third exemplary embodiment is the formation of an auxiliary active layer located close to one of an upper reflective layer and a lower reflective layer or is the formation of auxiliary active layers located close to both of an upper reflective layer and a lower reflective layer included in an optical cavity of a VCSEL. A second feature is the fact that the peak wavelength of the gain spectrum of the auxiliary active layer is set to a wavelength shorter than the peak wavelength of the gain spectrum of a main active layer in order to improve operation at high temperatures. In the third exemplary embodiment illustrated in FIG. 8, descriptions will be made by taking the case where the auxiliary reflective layer is formed close to the lower reflective layer as an example.

A VCSEL 61 according to the third exemplary embodiment has substantially the same structure as the VCSEL 41 according to the second exemplary embodiment. That is, the VCSEL 61 includes an optical cavity 63 on the upper surface of a substrate 62. The optical cavity 63 includes a lower reflective layer 64, a barrier layer 68, an auxiliary active layer 67 (second active layer), a first cladding layer 69, a main active layer 66 (first active layer), a second cladding layer 70, and an upper reflective layer 65 stacked in that order. An n-type electrode 71 is formed on the lower surface of the substrate 62. A p-type electrode 72 having an opening 72A is formed on the upper surface of the upper reflective layer 65.

The main active layer 66 is arranged in the middle portion of the optical cavity 63 in the thickness direction. Like the main active layer 46 according to the second exemplary embodiment, the main active layer 66 has a multiple-quantum-well structure that includes, for example, three well sublayers 66A, 66B, and 66C functioning as quantum wells. A barrier layer 66D is formed between the well layers 66A and 66B. A barrier layer 66E is formed between the well sublayers 66B and 66C.

The auxiliary active layer 67 is arranged in the vicinity of the lower reflective layer 64 with the barrier layer 68. Like the auxiliary active layer 47 according to the second exemplary embodiment, the auxiliary active layer 67 has a single-quantum-well structure.

Unlike the main active layer 46 and the auxiliary active layer 47 according to the second exemplary embodiment, the peak wavelength of the gain spectrum of the auxiliary active layer 67 is shorter than the peak wavelength of the gain spectrum of the main active layer 66. Specifically, the peak wavelength of the gain spectrum of the main active layer 66 is set to, for example, about 848 nm. The peak wavelength of the gain spectrum of the auxiliary active layer 67 is set to, for example, about 835 nm.

Like the first cladding layer 49 according to the second exemplary embodiment, the physical (effective) length of the first cladding layer 69 in the thickness direction is reduced by a value corresponding to, for example, the auxiliary active layer 67 with respect to the physical (effective) length of the second cladding layer 70. In this way, the optical length of the first cladding layer 69 is adjusted by a reduction method to offset the optical length of the auxiliary active layer 67, so that the optical length Lo between the lower reflective layer 64 and the upper reflective layer 65 included in the optical cavity 63 is kept constant.

The VCSEL 61 according to the third exemplary embodiment has the foregoing structure. The light-emitting operation of the VCSEL 61 is the same as that of the VCSEL 1 according to the first exemplary embodiment. The VCSEL 61 has the same effect as in the first exemplary embodiment. Furthermore, in the third exemplary embodiment, the auxiliary active layer 67 exhibiting the gain spectrum whose peak wavelength is shorter than the peak wavelength of the gain spectrum of the main active layer 66 is formed, thereby leading to stable operating characteristics even if the operating temperature is changed from room temperature to a high temperature. This effect will be specifically described below.

As illustrated in FIG. 5, when the operating temperature of the VCSEL is changed from room temperature to a high temperature, the gain spectrum of the active layer shifts entirely to longer wavelengths and changes similarly in such a manner that the maximum gain coefficient is reduced.

The resonant wavelength λ0 of light emitted from the VCSEL 61 is determined by the optical length Lo between the upper reflective layer 65 and the lower reflective layer 64 included in the optical cavity 63 of the VCSEL 61. The coefficient of linear expansion and the refractive index of each of media constituting the optical cavity 63 are not significantly changed. So, the resonant wavelength λ0 of light is not significantly changed. The temperature characteristics of the VCSEL 61 are thus dominated by the temperature dependence of the quantum wells constituting the main active layer 66 and the auxiliary active layer 67.

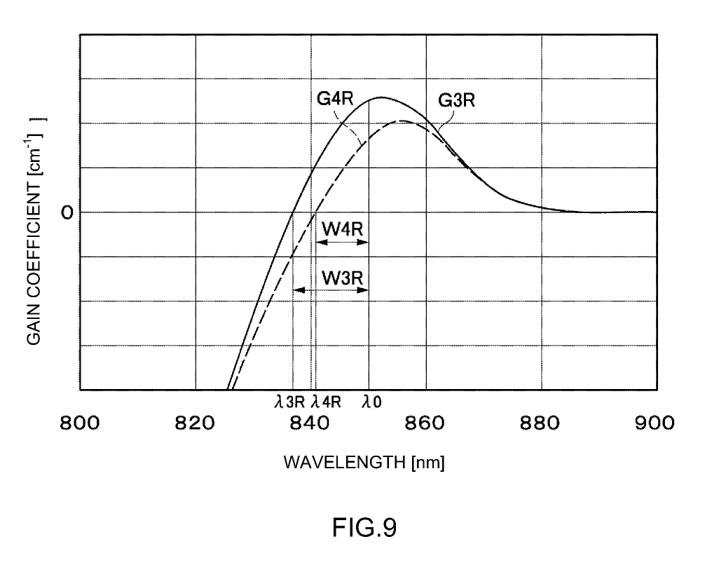

FIG. 9 illustrates the gain spectrum G3R of the VCSEL 61 including the main active layer 66 and the auxiliary active layer 67 in simulations at room temperature. The gain spectrum G3R has a profile obtained by the superimposition of the gain spectrum of the main active layer 66 and the gain spectrum (not shown) of the auxiliary active layer 67. To demonstrate the effect of the auxiliary active layer 67 formed in the VCSEL 61, FIG. 8 also illustrates the gain spectrum G4R of a VCSEL including the main active layer 66 without the auxiliary active layer 67 in simulations. The simulations were performed under conditions described below. The peak wavelength of the gain spectrum of the main active layer 66 was set to about 845 nm. The peak wavelength of the gain spectrum of the auxiliary active layer 67 was set to about 835 nm. The number of carriers injected into the main active layer 66 was identical to the number of carriers injected into the auxiliary active layer 67. For example, the number of carriers was about 2.0×10¹⁸ carriers/cm³. Furthermore, the resonant wavelength λ0 of the VCSEL 61 is set in a frequency range where the gain coefficient of the gain spectrum G3R is positive.

The peak wavelength of the gain spectrum of the auxiliary active layer 67 is selected in such a manner that the gain coefficient of the gain spectrum G3R is larger than the gain coefficient of the gain spectrum G4R in a frequency range corresponding to wavelengths shorter than the peak wavelength of the gain spectrum G4R when the gain spectrum of the auxiliary active layer 67 is superimposed on the gain spectrum G4R of the main active layer 66. Wavelengths (frequencies) on the shorter-wavelength side when each of the gain coefficient of the gain spectrum G3R and the gain coefficient of the gain spectrum G4R is zero are set to λ3R and λ4R, respectively. In the case where the frequency range between the resonant wavelength λ0 and the wavelength λ3R is set to W3R and where the frequency range between the resonant wavelength λ0 and the wavelength λ4R is set to W4R, the frequency range W3R is wider than the frequency range W4R.

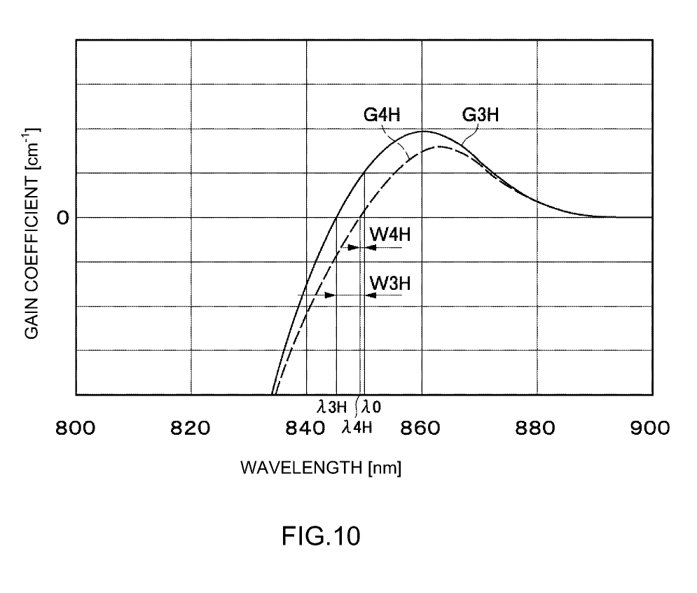

Next, in the case where the operating temperature of the VCSEL 61 is changed from room temperature (e.g., about 25° C.) to a high temperature (e.g., about 50° C.), descriptions will be made with reference to FIG. 10.

When the operating temperature is changed from room temperature to a high temperature, the gain spectrum G3R is shifted to longer wavelengths and changed into a gain spectrum G3H. Furthermore, the gain spectrum G4R is also shifted to longer wavelengths and changed into a gain spectrum G4H.

Wavelengths (frequencies) on the shorter-wavelength side when each of the gain coefficient of the gain spectrum G3H and the gain coefficient of the gain spectrum G4H is zero are set to λ3H and λ4H, respectively. The frequency range between the resonant wavelength λ0 and the wavelength λ3H is set to W3H. The frequency range between the resonant wavelength λ0 and the wavelength λ4H is set to W4H.

In this case, since the gain spectrum G4R is shifted to longer wavelengths, the frequency range W4H is narrower than the frequency range W4R, which is a very narrow range. Meanwhile, the frequency range W3R is wider than the frequency range W4R. Unlike the frequency range W4H, even if the gain spectrum G3R is shifted to longer wavelengths, the frequency range W3H is not significantly narrow but has a certain width. It is thus possible to ensure a certain gain coefficient in a range around the resonant wavelength λ0 even if the operating temperature of the VCSEL 61 is changed from room temperature to a high temperature.

In a frequency range corresponding to wavelengths longer than the peak wavelength of the gain spectrum G3H, the gain coefficient of the gain spectrum G3H is lower than that of the gain spectrum G3R but is closer to the gain coefficient of the gain spectrum G4R. It is thus possible to ensure a wide frequency range where the gain coefficient is positive in a wavelength range including the resonant wavelength λ0 in comparison with the case where the main active layer 66 is formed without the formation of the auxiliary active layer 67. Hence, the VCSEL 61 operates stably even if the operating temperature is changed from room temperature to a high temperature. That is, the formation of the auxiliary active layer 67 complements a reduction in gain coefficient in a frequency range corresponding to wavelengths shorter than the peak wavelength, suppresses a reduction in gain coefficient in a frequency range corresponding to wavelengths longer than the peak wavelength, and allows the VCSEL 61 to operate stably even if the operating temperature is changed from room temperature to a high temperature.

In the foregoing third exemplary embodiment, the auxiliary active layer 67 is formed at one position below the main active layer 66. Like the first embodiment, auxiliary active layers can be formed at positions above and below the main active layer. Alternatively, an auxiliary active layer can be formed at one position above the main active layer.

In the foregoing third exemplary embodiment, the auxiliary active layer 67 has a single-quantum-well structure. Alternatively, the auxiliary active layer 67 can have a multiple-quantum-well structure.

In the second and third exemplary embodiments, the reduction method includes forming the first cladding layer 49 and the first cladding layer 69 in such a manner that each of the first cladding layer 49 and the first cladding layer 69 has a short physical (effective) length. However, the present invention is not limited to this reduction method. As another reduction method, for example, the first cladding layer 49 and the first cladding layer 69 can be formed, without changing their physical (effective) lengths, using a material having a lower refractive index than that of the cladding layer used when the auxiliary active layer 47 and the auxiliary active layer 67 are not formed.

In the foregoing exemplary embodiments, the descriptions are made by taking the 0.8-μm-band VCSELs 1, 41, and 61 as examples. Embodiments of the present invention can be applied to surface emitting devices that emit light having longer wavelengths than light from the VCSELs described above. Alternatively, embodiments of the present invention can be applied to surface emitting devices that emit light having shorter wavelengths than light from the VCSELs described above.

In the foregoing exemplary embodiments, each of the main active layers 6, 46, and 66 has a multiple-quantum-well structure including the three well sublayers 6A to 6C, 46A to 46C, or 66A to 66C. A multiple-quantum-well structure including two or four or more well sublayers can be used. Alternatively, a single-quantum-well structure can be used.

In the foregoing exemplary embodiments, the optical lengths Lo between the lower reflective layers 4, 44, and 64 and the upper reflective layers 5, 45, and 65 included in the optical cavities 3, 43, and 63 are set to values equal to the wavelengths λ of light emitted, i.e., one wavelength. However, the present invention is not limited thereto. For example, like Japanese Unexamined Patent Application Publication No. 2007-87994, the optical length between the lower reflective layer and the upper reflective layer may be set to a value 1.5 or more times the wavelength λ of light or a value (e.g., 1.5λ, 2λ, or 2.5λ). In this case, a main active layer (first active layer) is formed, and one or more auxiliary active layers (second active layers) are formed close to one or both of an upper reflective layer and a lower reflective layer included in an optical cavity, the main active layer and the one or more auxiliary active layers being located at plural antinodes of a standing wave.

In the foregoing exemplary embodiments, the descriptions of the surface emitting devices are made by taking the VCSELs 1, 41, and 61 as examples. Alternatively, embodiments of the present invention can be applied to surface emitting diodes (LED) serving as surface emitting devices.

While preferred embodiments of the invention have been described above, it is to be understood that variations and modifications will be apparent to those skilled in the art without departing from the scope and spirit of the invention. The scope of the invention, therefore, is to be determined solely by the following claims and their equivalents.

What is claimed is:

1. A surface emitting device comprising:
an optical cavity including
a first active layer,
a pair of reflective layers, the first active layer being arranged between the pair of reflective layers, the reflective layers being opposite each other, the optical cavity forming a standing wave including antinodes where the maximum amplitude of light is obtained, and each of the antinodes being located in the vicinity of a corresponding one of the pair of reflective layers,
a second active layer formed in the vicinity of at least one of the pair of reflective layers, and
a cladding layer formed between the pair of reflective layers,
wherein the cladding layer is formed by a reduction method for reducing the physical length or optical length of the cladding layer to offset an increase in the physical length or optical length between the pair of reflective layers due to the formation of the cladding layer and the second active layer between the pair of reflective layers.

2. The surface emitting device according to claim 1, wherein the reduction method includes forming the cladding layer such that the physical length of the cladding layer offsets the increase in the physical length or optical length between the pair of reflective layers.

3. The surface emitting device according to claim 1, wherein the reduction method includes forming a film that serves as the cladding layer of a low-refractive-index material such that the cladding layer has an optical length that offsets said increase in the physical length or optical length between the pair of reflective layers.

4. The surface emitting device according to claim 1, wherein the peak wavelength of the gain spectrum of the second active layer is set to a wavelength longer than the peak wavelength of the gain spectrum of the first active layer,
whereby a gain coefficient of the gain spectrum of the second active layer shifted to shorter wavelengths due to a change in operating temperature from room temperature to a low temperature is superimposed on a frequency range where a gain coefficient of the gain spectrum of the first active layer is reduced by the shift of the gain spectrum of the first active layer to shorter wavelengths due to a change in operating temperature from room temperature to a low temperature, complementing a reduction in the gain coefficient of the first active layer.

5. The surface emitting device according to claim 2, wherein the peak wavelength of the gain spectrum of the second active layer is set to a wavelength longer than the peak wavelength of the gain spectrum of the first active layer,
whereby a gain coefficient of the gain spectrum of the second active layer shifted to shorter wavelengths due to a change in operating temperature from room temperature to a low temperature is superimposed on a frequency range where a gain coefficient of the gain spectrum of the first active layer is reduced by the shift of the gain spectrum of the first active layer to shorter wavelengths due to a change in operating temperature from room temperature to a low temperature, complementing a reduction in the gain coefficient of the first active layer.

6. The surface emitting device according to claim 3, wherein the peak wavelength of the gain spectrum of the second active layer is set to a wavelength longer than the peak wavelength of the gain spectrum of the first active layer,
whereby a gain coefficient of the gain spectrum of the second active layer shifted to shorter wavelengths due to a change in operating temperature from room temperature to a low temperature is superimposed on a frequency range where a gain coefficient of the gain spectrum of the first active layer is reduced by the shift of the gain spectrum of the first active layer to shorter wavelengths due to a change in operating temperature from room temperature to a low temperature, complementing a reduction in the gain coefficient of the first active layer.

7. The surface emitting device according to claim 1, wherein the peak wavelength of the gain spectrum of the second active layer is set to a wavelength shorter than the peak wavelength of the gain spectrum of the first active layer,
whereby a gain coefficient of the gain spectrum of the second active layer shifted to longer wavelengths due to a change in operating temperature from room temperature to a high temperature is superimposed on a frequency range where a gain coefficient of the gain spectrum of the first active layer is reduced by the shift of the gain spectrum of the first active layer to longer wavelengths due to a change in operating temperature from room temperature to a high temperature, complementing a reduction in the gain coefficient of the first active layer.

8. The surface emitting device according to claim 2, wherein the peak wavelength of the gain spectrum of the second active layer is set to a wavelength shorter than the peak wavelength of the gain spectrum of the first active layer,
whereby a gain coefficient of the gain spectrum of the second active layer shifted to longer wavelengths due to a change in operating temperature from room temperature to a high temperature is superimposed on a frequency range where a gain coefficient of the gain spectrum of the first active layer is reduced by the shift of the gain spectrum of the first active layer to longer wavelengths due to a change in operating temperature from room temperature to a high temperature, complementing a reduction in the gain coefficient of the first active layer.

9. The surface emitting device according to claim 3, wherein the peak wavelength of the gain spectrum of the second active layer is set to a wavelength shorter than the peak wavelength of the gain spectrum of the first active layer,
whereby a gain coefficient of the gain spectrum of the second active layer shifted to longer wavelengths due to a change in operating temperature from room temperature to a high temperature is superimposed on a frequency range where a gain coefficient of the gain spectrum of the first active layer is reduced by the shift of the gain spectrum of the first active layer to longer wavelengths due to a change in operating temperature from room temperature to a high temperature, complementing a reduction in the gain coefficient of the first active layer.

10. The surface emitting device according to claim 1, wherein the standing wave has a length corresponding to one wavelength of the light.

11. The surface emitting device according to claim 1, wherein said cladding layer is a first of a pair of first and second cladding layers, and said second cladding layer has a physical or optical length different from said first cladding layer.

12. A surface emitting device comprising:
an optical cavity including
a first active layer,
a pair of reflective layers, the first active layer being arranged between the pair of reflective layers, the reflective layers being opposite each other, the optical cavity forming a standing wave including antinodes where the maximum amplitude of light is obtained, and each of the antinodes being located in the vicinity of a corresponding one of the pair of reflective layers, and
a second active layer formed in the vicinity of at least one of the pair of reflective layers.
